(19) United States
(12) Patent Application Publication
(10) Pub. No.: US 2016/0338214 A1
(43) Pub. Date: Nov. 17, 2016

(54) ELECTRONIC DEVICE SHELL

(71) Applicant: SHAO-QIN WEN, Jinchang City (CN)

(72) Inventor: SHAO-QIN WEN, Jinchang City (CN)

(21) Appl. No.: 15/147,903

(22) Filed: May 5, 2016

(30) Foreign Application Priority Data
May 12, 2015 (CN) 201520308850.8

(51) Int. Cl. H05K 5/02; H05K 5/03

(52) U.S. Cl. CPC H05K 5/0243; H05K 5/03

(57) ABSTRACT

An electronic device shell includes a shell body and a transparent cover. The transparent cover is connected with the shell body along a thickness direction of the shell body. The shell defines an image receiving space between the shell body and the transparent cover.

### BACKGROUND OF THE INVENTION

1. Field of the Invention

The present invention relates to an electronic device shell, and more particularly to an electronic device shell having an image receiving space for receiving a favorite image, such as a photo, a drawing, a card, etc.

2. Description of Related Art

The study showed that the loyalty and enthusiasm of consumers to a brand are more from the appearance of the product. The beautiful appearance of a product attracts consumers more than the performance and price. Especially in the field of consumer electronic device, the appearance of an electronic device is a very important factor to determine its market competitiveness. Some manufacturers have introduced private customized service that is printing favorite patterns of individual consumers. However, the pattern is permanent and can not be replaced.

Hence, it is desirable to provide an improved electronic device shell for solving above problems.

### BRIEF SUMMARY OF THE INVENTION

The present invention provides an electronic device shell including a shell body. The shell body defines an image receiving space. The image receiving space is provided with an opening being opened outwardly.

In another aspect, the present invention also provides an electronic device shell including a shell body and a transparent cover. The transparent cover is connected with the shell body along a thickness direction of the shell body. The electronic device shell defines an image receiving space between the shell body and the transparent cover.

In a third aspect, the present invention also provides an electronic device shell including an inner surface and an outer surface opposite to the inner surface. The electronic device shell further defines an image receiving space between the inner surface and the outer surface, and the outer surface is transparent.

The foregoing has outlined rather broadly the features and technical advantages of the present invention in order that the detailed description of the invention that follows may be better understood. Additional features and advantages of the invention will be described hereinafter which form the subject of the claims of the invention.

### BRIEF DESCRIPTION OF THE DRAWINGS

The components in the drawing are not necessarily drawn to scale, the emphasis instead being placed upon clearly illustrating the principles of the described embodiments. In the drawings, reference numerals designate corresponding parts throughout various views, and all the views are schematic.

FIG. 1 is a perspective view of an electronic device shell in accordance with an illustrated embodiment of the present invention, and the electronic device shell is inserted with an image;

FIG. 2 is a perspective view of the electronic device shell shown in FIG. 1, while the image is divided from the electronic device shell.

### DETAILED DESCRIPTION OF THE PREFERRED EMBODIMENT

Reference will now be made to the drawing figures to describe the embodiments of the present invention in detail. In the following description, the same drawing reference numerals are used for the same elements in different drawings.

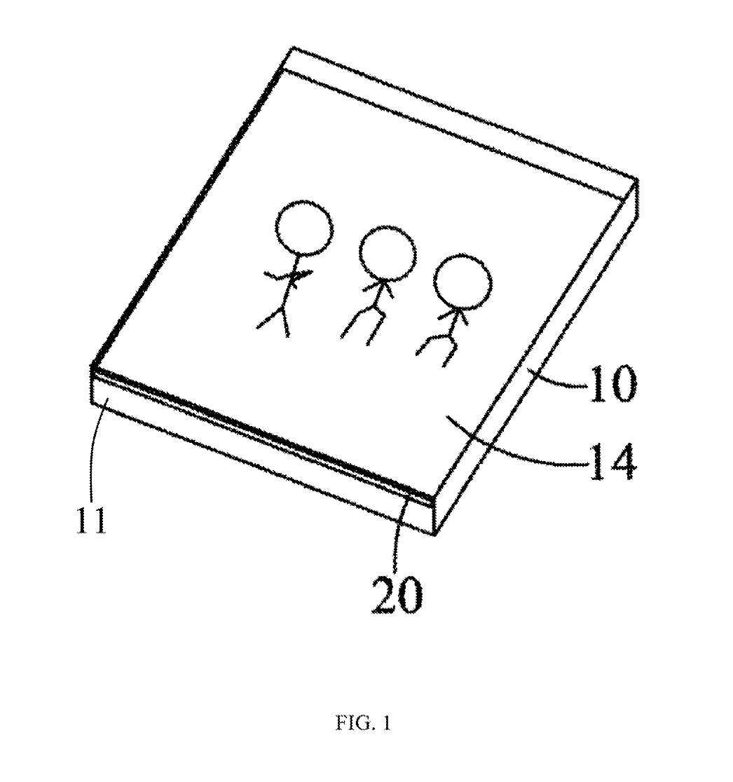

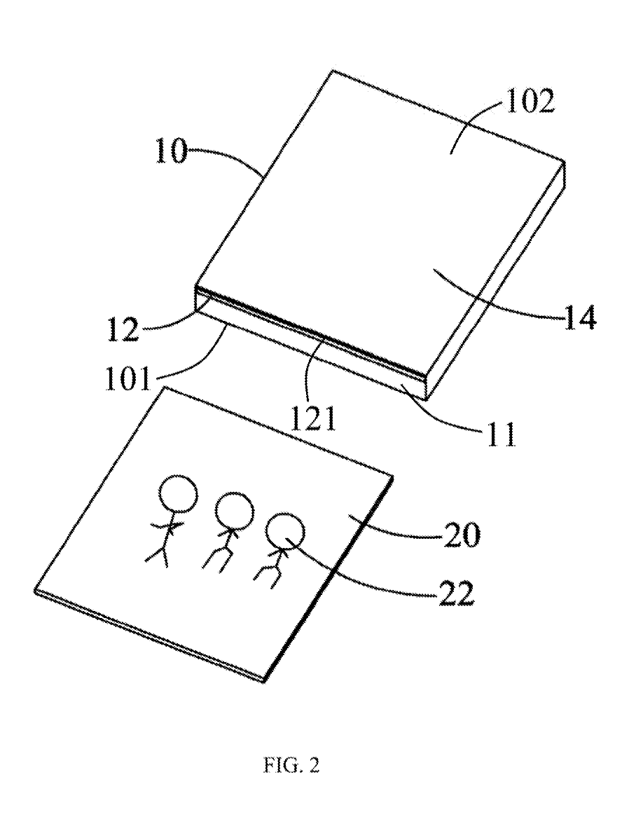

Referring to FIGS. 1 to 2, the present invention discloses an electronic device shell 10. The electronic device is a mobile phone, or a removable hard drive, or a tablet or a portable power etc.

Referring to FIG. 2, the electronic device shell 10 has a shell body 11. The shell body 11 defines an image receiving space 12. The image receiving space 12 is provided with an opening 121 being opened outwardly for an image 20, such as a photo, a drawing, a card, etc being inserted into the image receiving space 12 from there. The image 20 is printed with favorite patterns 22 of individual consumers.

The image receiving space 12 presents as flat or curved shape. The opening 121 is opened sideward.

Preferably, the electronic device shell 10 further has a transparent cover 14 connected with the shell body 11 along a thickness direction of the shell body 11. The image receiving space 12 is located between the transparent cover 14 and the shell body 11. The shell body 11 and the transparent cover 14 are formed integrally or separately.

Referring to FIG. 1, when inserting the image 20 into the image receiving space 12, the favorite patterns 22 shown on the image 20 can be seen through the transparent cover 14. Therefore, the individual consumers can insert or change different images 20 into the image receiving space 12 to get different appearance of the electronic device shell 10 according to their preferences. Besides, the replacement of the images 20 is easy, convenient and has low cost.

Besides, in an alternative embodiment, the electronic device shell 10 can be designed to have an inner surface 101, an outer surface 102 opposite to the inner surface 101 and an image receiving space 12 between the inner surface 101 and the outer surface 102. The image receiving space 12 is provided with an opening 121 opened sideward for inserting an image 20 into the image receiving space 12. The outer surface 102 is transparent to show the favorite patterns 22 of the image 20 outward.

It is to be understood, however, that even though numerous characteristics and advantages of preferred and exemplary embodiments have been set out in the foregoing description, together with details of the structures and functions of the embodiments, the disclosure is illustrative only; and that changes may be made in detail within the principles of present disclosure to the full extent indicated by the broadest general meaning of the terms in which the appended claims are expressed.

What is claimed is:

1. An electronic device shell, comprising:
a shell body defining an image receiving space;
wherein the image receiving space is provided with an opening being opened outwardly.

2. The electronic device shell as claimed in claim 1, further comprising a transparent cover connected with the shell body along a thickness direction of the shell body, the image receiving space is located between the transparent cover and the shell body.

3. The electronic device shell as claimed in claim 2, wherein the shell body and the transparent cover are formed integrally or separately.

4. The electronic device shell as claimed in claim 1, wherein the opening is opened sideward.

5. The electronic device shell as claimed in claim 1, wherein the image receiving space presents as flat or curved shape.

6. The electronic device shell as claimed in claim 4, wherein the electronic device is a mobile phone, or a removable hard drive, or a tablet or a portable power.

7. An electronic device shell comprising:
a shell body; and
a transparent cover connected with the shell body along a thickness direction of the shell body;
wherein the electronic device shell defines an image receiving space between the shell body and the transparent cover.

8. The electronic device shell as claimed in claim 7, wherein the image receiving space is provided with an opening opened sideward for inserting an image into the image receiving space.

9. The electronic device shell as claimed in claim 7, wherein the image receiving space presents as flat or curved shape.

10. The electronic device shell as claimed in claim 7, wherein the electronic device is a mobile phone, or a removable hard drive, or a tablet or a portable power.

11. An electronic device shell comprising:
an inner surface; and
an outer surface opposite to the inner surface;
wherein the electronic device shell further defines an image receiving space between the inner surface and the outer surface, and the outer surface is transparent.

12. The electronic device shell as claimed in claim 11, wherein the image receiving space is provided with an opening opened sideward for inserting an image into the image receiving space.

13. The electronic device shell as claimed in claim 11, wherein the image receiving space presents as flat or curved shape.

14. The electronic device shell as claimed in claim 11, wherein the electronic device is a mobile phone, or a removable hard drive, or a tablet or a portable power.
